(19) United States
(12) Patent Application Publication
(10) Pub. No.: US 2017/0301907 A1
(43) Pub. Date: Oct. 19, 2017

(54) METHOD AND APPARATUS FOR USING DISTRIBUTED BATTERY MANAGEMENT SYSTEM CIRCUIT BOARDS AS DC BUSSES IN AN ENERGY STORAGE SYSTEM

(71) Applicant: Pathion Inc., Los Gatos, CA (US)

(72) Inventors: David F. Park, Los Gatos, CA (US); David R. Smith, Los Gatos, CA (US); David C. Reuter, Los Gatos, CA (US); Daniel West, Los Gatos, CA (US)

(73) Assignee: Pathion Inc., Los Gatos, CA (US)

(21) Appl. No.: 15/439,205

(22) Filed: Feb. 22, 2017

Related U.S. Application Data
(63) Continuation of application No. PCT/US2015/046496, filed on Aug. 24, 2015.
(60) Provisional application No. 62/040,755, filed on Aug. 22, 2014.

(51) Int. Cl. H01M 2/34; H01G 11/74; H01M 2/10; H01M 2/20; H01M 16/00; H01G 11/10; H01M 12/00; H01M 10/42; H05K 1/18

(52) U.S. Cl. CPC H01M 2/34; H01M 16/00; H01G 11/74; H01M 2/1094; H01M 2/206; H05K 1/181; H01M 16/003; H01G 11/10; H01M 12/005; H01M 10/425; H01M 2010/4271; H05K 2201/10015; H05K 2201/10037; H05K 2201/10181

(57) ABSTRACT

Described is a distributed battery management system that utilizes circuit boards as direct current busses for primary power in large-scale battery energy storage systems.

### BACKGROUND OF THE INVENTION

Large-format battery energy storage systems are useful for storing energy produced from any source. As illustrated in FIG. 1, a large-format battery energy storage system can store and controllably deliver energy produced from any source such as the electrical grid, solar panels, or wind turbines, among other examples. Such systems generally involve an array of batteries in electrical connection. The batteries can be arranged in a plurality of energy storage segments, or battery banks, that make up the energy storage system. Multiple battery banks can be configured in connected modular units, as illustrated in FIG. 2. A battery management system is an electronic system that manages battery cells in such an energy storage system.

Demand for large-format energy storage systems is growing rapidly as markets for electric vehicles and stationary energy storage grow. Sales of lithium-ion batteries for light-duty consumer electric vehicles alone are expected to exceed $24 billion by 2023, while stationary energy storage is projected to grow to more than $30 billion by 2022 for a range of applications that include renewable energy integration, ancillary services, microgrid support, demand charge reduction, and backup power.

Most large-format battery energy storage systems include large numbers of battery cells that are electrically connected in series and parallel configurations in order to meet desired energy, power, and voltage specifications. Generally, primary power (i.e., power that is extracted from battery cells for use in large-format energy storage applications, as opposed to the smaller loads which may be drawn for monitoring, controls, communication, or other ancillary uses) is transmitted through wires, bus bars, or similar conductors that are typically soldered, welded, or fastened with threaded connectors to battery terminals. Battery cells that are arranged in a series string generally include connections of this sort from the positive terminal of one cell to the negative terminal of the next cell, while battery cells that are arranged in a parallel configuration feature such connections between the positive terminals of each cell and separately for the negative terminals of each cell within the parallel string.

It would be advantageous to develop new and improved battery storage systems and battery management systems.

### SUMMARY OF THE INVENTION

Provided herein is a distributed battery management system that utilizes circuit boards as direct current busses for primary power in a large-scale battery energy storage system. Each circuit board includes surface-mounted conducting traces which electrically connect the battery cells in series or in parallel. The surface-mounted conducting traces have large surface areas so as to dissipate and conduct heat away from the circuit boards.

Provided is a distributed battery management system that includes a plurality of battery cells having at least a first battery cell and a second battery cell, where each battery cell has electrical terminals including a negative terminal and a positive terminal. The distributed battery management system further includes a circuit board having an electrical connection to at least one of the electrical terminals, and one or more conducting traces mounted on the surface of the circuit board. The conducting traces are arranged such that at least one conducting trace establishes electrical contact between either (i) the negative terminal of the first battery cell and the positive terminal of the second battery cell in a series configuration, or (ii) the negative terminal of the first battery cell and the negative terminal of the second battery cell in a parallel configuration. Furthermore, at least one conducting trace is configured to serve as a primary power conduit for the one or more battery cells. The conducting traces have an aspect ratio of at least about 1.25:1. In certain embodiments, the conducting traces are from about 2 mm to about 8 mm thin, and from about 1 cm to about 5 cm wide.

In some embodiments, the battery cells are thermally isolated from each other. The battery cells can be spaced apart from each other so as to provide the thermal isolation between the battery cells, and/or the system can include an insulating material between any two battery cells. The insulating material can be any of silicon rubber, Teflon, acrylonitrile butadiene styrene, acetates, acrylics, ceramics, fiberglass laminates, thermoplastics, high impact polystyrene, polyimide, melamine, neoprene, nylon, polyethylene terephthalate, phenolics, polyolefins, polycarbonate, polysulfone, polyurethane, polyvinylchloride, polyphenylene sulfide, or combinations thereof.

In some embodiments, the electrical contact between one or more battery cells and the circuit board is established by means of a tension mechanism which applies mechanical pressure between a battery cell terminal and an electrical contact on the circuit board. In such embodiments, the battery cell terminal can be modified with a conductive spring, a conductive tab, a pin, or a secondary connector.

The system can include multiple subsets of battery cells. In certain embodiments, the conducting traces are configured such that the resistance between any two electrically adjacent battery cells is identical. Furthermore, the system can contain an identical amount of conductive material between any two battery cells.

The conducting traces can be configured such that the traces and/or circuit board melt or otherwise fail so as to sever an electrical connection under temperature or current levels corresponding to predetermined current and/or temperature limitations. This allows for a convenient method of fault isolation.

The system can further include one or more integrated circuits, such as a balancing circuit integrated onto the circuit board or any monitoring, control, or communication components or circuitry.

In some embodiments, the system balances at a power rating of from about 2 watts per battery cell to about 30 watts per battery cell.

In some embodiments, series interconnections and/or power transfer between the battery cells are fed through external circuitry attached to a mechanical safety lever, shield, or enclosure. The system can further include an electrical disconnect configured to break the series connections upon engaging the safety lever, shield, or enclosure.

Further provided is an energy generation or storage system featuring a distributed energy management system. The system includes a circuit board in electrical communication with subsets of a plurality of energy generation components or energy storage components, where the size of each subset ranges from a single energy generation component or energy storage component to all energy generation components or energy storage components within the system, and each energy generation component or energy storage component has electrical terminals including a negative terminal and a positive terminal. The system further includes one or more surface-mounted conducting traces arranged such that at least one surface-mounted conducting trace establishes electrical contact between either: (i) the negative terminal of one energy generation component or energy storage component and the positive terminal of an adjacent energy generation component or energy storage component in a series configuration; or (ii) two or more negative terminals and/or two or more positive terminals of adjacent energy generation components or energy storage components in a parallel electrical configuration. The conducting traces are further arranged such that at least one surface-mounted conducting trace serves as a primary power conduit for one or more of the electrically contacted energy generation components or energy storage components. In some embodiments, the energy generation components or energy storage components are fuel cells, capacitors, hybrid battery-capacitors, or a combination thereof.

In certain embodiments, the electrical communication is established by a tension mechanism which applies mechanical pressure between a modified or unmodified energy generation component or energy storage component terminal and an electrical contact on the circuit board.

In some embodiments, the surface-mounted conducting traces are configured such that the resistance between one energy generation component or energy storage component terminal and the terminal of an electrically adjacent energy generation component or energy storage component is identical to the resistance between another energy generation component or energy storage component terminal and a respective electrically adjacent energy generation component or energy storage component terminal within the system.

In some embodiments, the surface-mounted conducting traces are configured such that the conducting trace and/or the circuit board melts or otherwise fails so as to sever the corresponding electrical connection under temperature or current levels corresponding to predetermined current and/or temperature limitations.

In some embodiments, the energy generation or storage system featuring a distributed energy management system further includes a balancing circuit integrated onto the circuit board.

In some embodiments, the energy generation or storage system featuring a distributed energy management system further includes one or more integrated circuits on the circuit board. Such integrated circuits can include monitoring, controls, or communication components or circuitry.

Further provided is a method of isolating a fault in a battery storage system. The method involves providing a battery storage system that has circuit boards with surface-mounted conducting traces, where the conducting traces electrically connect the circuit boards to a plurality of battery cells, and tuning the dimensions of the conducting traces so as to cause the conducting traces to melt at a predetermined current and/or temperature level and thereby isolate a fault in the battery storage system.

Various aspects of this disclosure will become apparent to those skilled in the art from the following detailed description of the preferred embodiments, when read in light of the accompanying drawings.

### BRIEF DESCRIPTION OF THE DRAWINGS

FIG. 1: Non-limiting illustration of an energy storage system tied to the power grid, a solar panel, and wind turbine, configured to deliver the stored energy to a home.

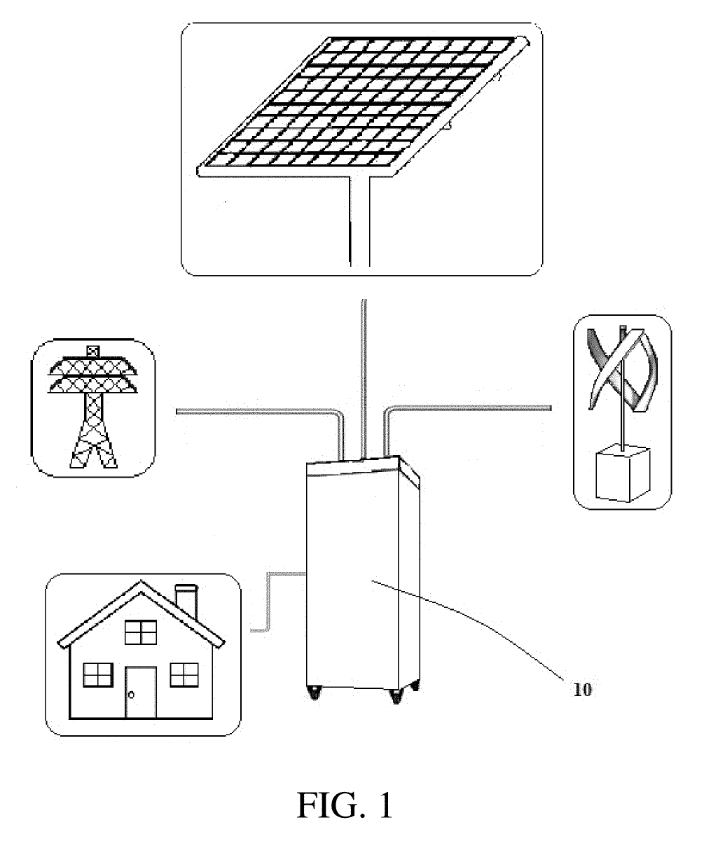

FIG. 2: Non-limiting illustration of battery banks in an energy storage system.

FIG. 3: Diagram that depicts a first embodiment of a distributed battery management system circuit board featuring conducting traces as primary power conduits.

FIG. 4: Diagram that depicts a second embodiment of a distributed battery management system circuit board featuring conducting traces as primary power conduits.

FIGS. 5A-5E: Non-limiting illustrations of a variety of alternative embodiments of cell terminal connectors.

FIG. 6: Diagram that depicts a third embodiment of a distributed battery management system circuit board featuring conducting traces as primary power conduits.

### DETAILED DESCRIPTION

The present disclosure relates in general to energy storage system management. Battery management systems are electronic systems that manage a plurality of batteries connected in series or parallel to create a large-scale battery energy storage system. Battery management systems typically monitor variables such as the voltage, temperature, and state of charge of the batteries in the system, and can be used to balance the batteries so as to maximize the capacity of the system.

Described herein is a distributed battery management system that utilizes circuit boards as direct current busses for primary power in a large-scale battery energy storage system. In accordance with the present disclosure, circuit board traces can be used as primary power conduits between and from battery cells in large-format energy storage applications. Both large-format energy storage systems and the broader electronics industry have transmitted modest loads of power through circuit boards. However, such power transmission is typically used for either: (1) on-board consumption for data processing functions, monitoring components, balancing circuits, or indicators (such as LEDs); or (2) certain off-board applications that may include powering ancillary systems such as small displays, cooling fans, or communications components. Surprisingly, when surface-mounted conducting traces with large surface areas are properly configured on the circuit boards as primary power conduits between and from battery cells, it results in several advantages that include better system safety, improved performance, and ease of maintenance. It also enables the balancing of larger amounts of power in the system than conventional circuit board systems.

Generally speaking, rechargeable battery cells are energy storage elements that are capable of converting electrical energy to chemical energy when serving as a load, storing this chemical energy for a period of time, and converting the stored chemical energy to electrical energy when a load is applied to the cell. Exemplary battery cells include, but are not limited to: lithium ion, lithium iron phosphate, lithium sulfur, lithium titanate, nano lithium titanate oxide, nickel metal hydride, nickel cadmium, nickel hydrogen, nickel-iron, sodium sulfur, vanadium redox, rechargeable alkaline, or aqueous hybrid ion. The battery management system of the present disclosure can be applied with any of these types of battery cells (or others, if desired), as well as to fuel cells, capacitors, and hybrid battery-capacitor cells.

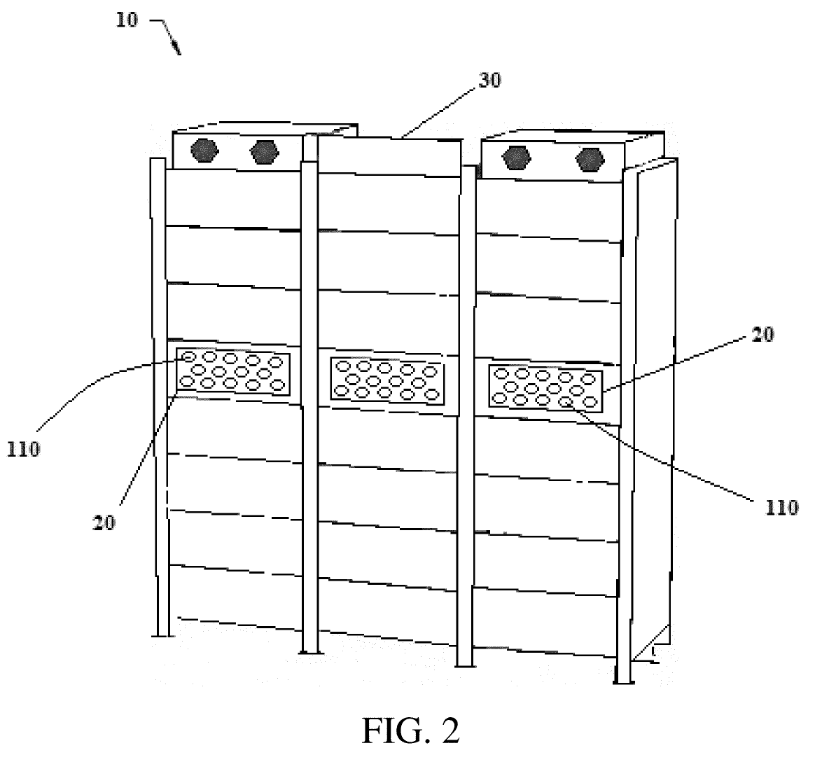

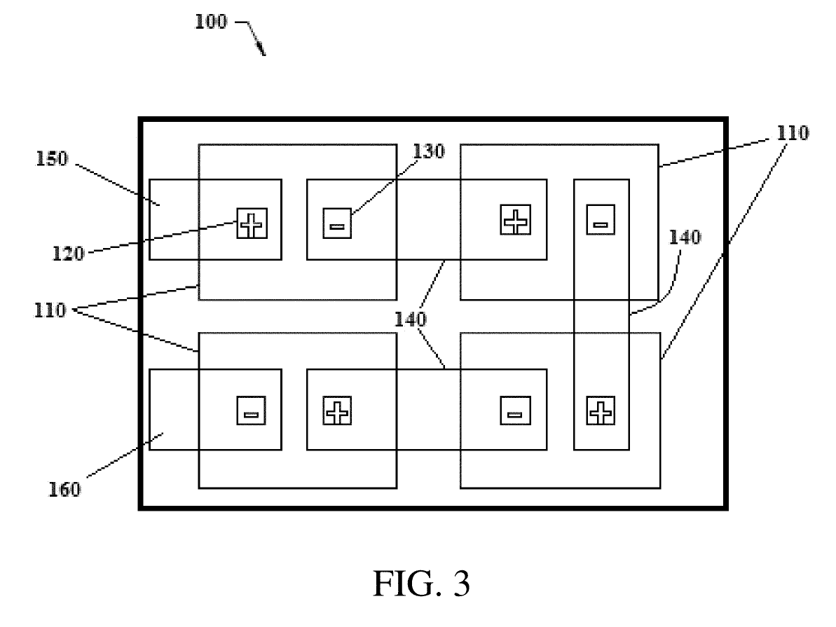

As shown in FIG. 2, an energy storage system 10 can include multiple battery banks 20 composed of multiple batteries 110, where the battery banks 20 can be housed in modular units 30. The distributed battery management system described herein disperses some or all of the functionality of a centralized battery management system throughout the various energy storage segments of a large-format energy storage system, integrating battery management system functionality with the primary power transmission architecture of the energy storage system. The battery management system makes primary power transmission a function of a distributed battery management system circuit board. A diagram of a first embodiment of an exemplary distributed battery management system circuit board is illustrated in FIG. 3. As shown therein, a circuit board 100 connects four battery cells 110 in series, meaning each positive battery terminal 120 is electrically connected to a negative battery terminal 130 of a different battery cell 110, with primary power transport between the four battery cells 110 occurring through the on-board conductor traces 140. Though the circuit board 100 shown in FIG. 3 is illustrated with four battery cells 110, it is understood that any number of battery cells can be utilized. An analogous architecture can be utilized to connect any number of such battery cells, in either series or parallel configurations.

The use of a circuit board conducting trace 140 as a primary power conduit within a high-power large-format energy storage system presents a number of challenges, not least of which is the susceptibility of the circuit board 100 to the stresses of high thermal loads that are intrinsic in such high-power applications. In particular, the use of embedded traces for such high-power transmission can lead to a breakdown of the circuit board material. To overcome this problem, the circuit board 100 utilizes conducting traces 140 that are thin and wide. The relatively large surface area of each trace 140 allows heat to be dissipated away from the circuit board 100 through natural radiation and convection processes. The conducting traces 140 can be from about 1 mm to about 10 mm thin, or from about 2 mm to about 8 mm thin. The traces can be from about 0.1 cm to about 10 cm wide, or from about 1 cm to about 5 cm wide. In one non-limiting example, the conducting traces 140 are from about 2 mm to about 8 mm thin, and from about 1 cm to about 5 cm wide.

The conducting traces 140 are wider than they are thin. In some embodiments, the conducting traces 140 have a width that is about ten times bigger than their thickness, or about five times bigger than their thickness. In some embodiments, the conducting traces 140 have a width that is at least about 125% the size of their thickness. Thus, the conducting traces have an aspect ratio, which is defined herein as being the ratio of width:thickness, of at least about 1.25:1. In some embodiments, the conducting traces have an aspect ratio of greater than 3:1, or greater than 5:1, or greater than 9:1. In some embodiments, the conducting traces have an aspect ratio as high as about 25:1.

To further overcome the problem of high-power transmission causing a breakdown of circuit board material, the conducting traces 140 are mounted on the surface of the circuit board 100 instead of being embedded within it. Being surface-mounted instead of embedded within the surface of the circuit board 100 allows for excellent electrical conductance, but significantly reduces thermal conductance both into the circuit board 100 and to adjacent components.

The thermal control advantages of the conducting trace architecture can also extend beyond the circuit board 100 to provide additional thermal isolation between components. Specifically, the circuit board 100 illustrated in FIG. 3 dissipates much of the heat transferred from the battery cells 110 to the power conduit trace 140 before this heat can be absorbed from the trace 140 by electrically adjacent cells. This characteristic is particularly advantageous in applications where a battery cell 110 may experience a thermal runaway event. Such thermal runaway events can generate a large amount of heat that, in typical large-format energy storage applications, can easily travel along wires or bus bars to electrically adjacent cells. Electrically adjacent cells exposed to these high thermal stresses are susceptible to being damaged or being forced into thermal runaway themselves.

The primary power conduction facilitated by the surface-mounted conducting traces 140 helps to prevent the propagation of thermal stress, component damage, and thermal runaway throughout any large-format energy storage system. Some embodiments of this architecture are further enhanced by thermally isolating the body of each battery cell 110 from other cells within the system, in addition to thermally isolating the electrical connections between cells. Such cell-body thermal isolation can be provided, for example, by inserting thermally insulating material layers between cells. This approach can utilize any suitable thermally insulating material such as, but not limited to: silicon rubber, Teflon, acrylonitrile butadiene styrene, acetates, acrylics, ceramics, fiberglass laminates, thermoplastics, high impact polystyrene, polyimide, melamine, neoprene, nylon, polyethylene terephthalate, phenolics, polyolefins, polycarbonate, polysulfone, polyurethane, polyvinylchloride, polyphenylene sulfide, or combinations thereof. It is understood that the insulating material can be in the form of electrical insulating paper, foam, tape, sleeving, or combinations thereof.

Alternatively, cell-body thermal isolation can be provided by simply mechanically configuring cells with empty space separating the cells from one another. This approach takes advantage of both the low thermal conductivity of air to mitigate heat transfer between battery cells, and the fluid properties of air to dissipate heat from the cells via unforced convection processes. It is understood that the empty space architecture can be combined with the insulating material approach within the same system, where two or more battery cells are separated by empty space and two or more different battery cells are separated by thermal insulating material.

The primary conductor circuit board architecture described herein can also be leveraged to provide automatic fault isolation of components that exhibit abnormal current or temperature signatures. Specifically, the thickness, width, and/or depth of penetration of each trace 140 into the circuit board can be tuned to a particular energy storage system or application such that the trace 140 or circuit board 100 melts or otherwise fails to conduct when exposed to predetermined sufficiently high currents or temperatures. In this manner, the circuit board 100 acts as a fuse between some or all of the battery cells 110 or, alternatively, at other conduction points, according to the board design. Because these fusing events generally necessitate repair or replacement of the circuit board 100, such embodiments can utilize this mechanism as a secondary or tertiary means of fault isolation. Thus, further provided herein is a method of isolating a fault in a battery storage system, where the method involves implementing a circuit board having surface-mounted traces which melt or otherwise fail to conduct at predetermined current and/or temperature levels.

One advantage of the use of a circuit board as a primary power transmission element within an energy storage system is the manufacturing precision of circuit boards, which is typically quite high. This precision allows traces to be designed and implemented such that the resistance between each battery cell is precisely uniform. Uniform inter-cell resistance allows battery cells within a multi-cell system to be charged and discharged evenly, thereby reducing some non-uniform cycling that can force cells out of balance.

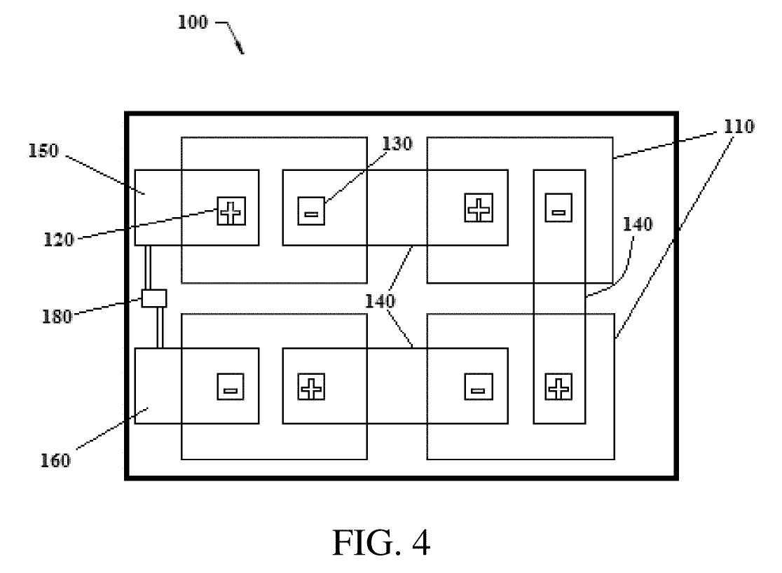

In addition to eliminating an intrinsic system feature that may complicate the maintenance of balance within a multi-cell energy storage system (namely, differentials in resistance between adjacent battery cells within the system), the architecture described herein is highly amenable to supporting distributed on-board balancing capabilities as well. Specifically, balancing circuits 180 for individual cells or groups of cells can be hosted on the same circuit board 100 that serves as the primary power conduit for the system, such as shown in FIG. 4. The aforementioned thermal advantages of the described circuit board 100, when combined with the proper resistors and other components, allow systems featuring the architecture described herein to balance at much higher power ratings than typical systems (on the order of from about 2 watts to about 30 watts per cell, as opposed to about 100 milliwatts per cell in typical systems).

Likewise, the same circuit board 100 used as a primary power conduit in the described system can support integrated circuitry and other components which may include monitoring elements, communications elements, data collection and processing elements, and other computational, control, and/or management components and circuits. This circuitry may operate independently, may be coupled with circuitry on other boards within the system, and/or may be used along with centralized BMS components. One function of additional on-board components may be to improve the performance of the board itself, for example through the addition of a power sink, such as a capacitor, to minimize voltage spikes.

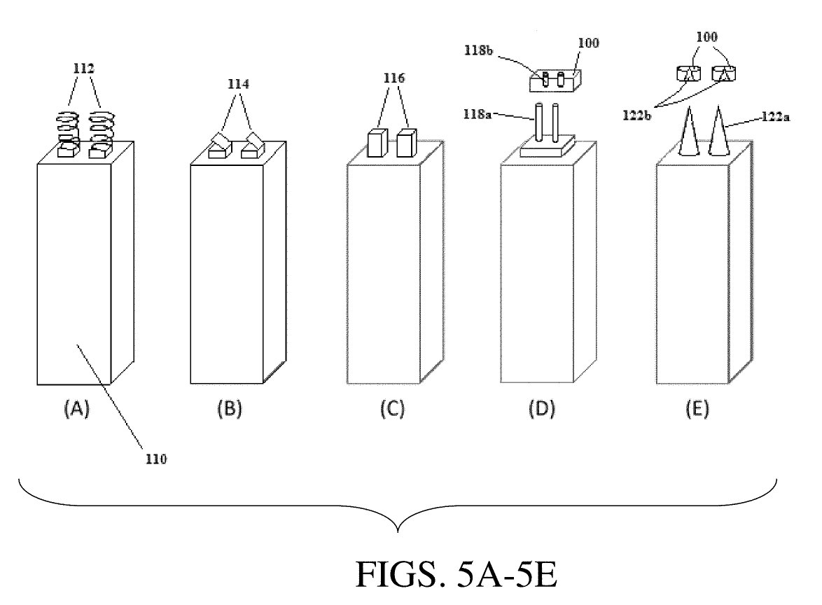

Embodiments of the described architecture that use circuit boards as primary power conduits within energy storage systems are highly amenable to alternative cell terminal connectors. In lieu of, or in combination with, conventional welds, solders, or threaded connectors such as screws or bolts, for example, the system may include tension connectors of various alternative forms. Referring now to FIG. 5A, one such alternative form includes one or more conductive springs 112 that are mechanically and electrically fastened to the battery cell terminals 120, 130 such that, when configured in an energy storage system, the springs 112 press against the proper contacts on the circuit board 100. Conversely, the same springs 112 can be mechanically and electrically fastened to the circuit board 100 such that, when configured in an energy storage system, the springs 112 press against the proper contacts of the battery cell 110.

Another alternative form is depicted in FIG. 5B, where one or more conductive tabs 114 are mechanically and electrically fastened to the battery cell terminals 120, 130 such that, when configured in an energy storage system, the tabs 114 press against the proper contacts on the circuit board 100. Conversely, the same tabs 114 can be mechanically and electrically fastened to the circuit board 100 such that, when configured in an energy storage system, the tabs 114 press against the proper contacts of the battery cell 110.

Another alternative form is depicted in FIG. 5C, where one or more battery terminal pins 116 (which may or may not feature additional conductive extensions) are mechanically and electrically fastened to the battery cell terminals 120, 130 such that, when the battery cell 110 is inserted into a properly configured system, the pins 116 allow the positive terminal 120 and negative terminal 130 of the battery cell 110 to press against the proper contacts on the circuit board 100. In this embodiment, the natural flex of the circuit board 100 provides the tension that ensures sufficient electrical contact between the battery cell terminals 120, 130 and the circuit board 100. Another alternative form is depicted in FIG. 5D, where one or more secondary or battery cell-integrated connectors 118 featuring male, female, mixed male and female, or an alternative contacting form factor is electrically connected to the positive and negative battery cell terminals 120, 130. Additionally, a complimentary female, male, mixed female and male, or an alternative contacting form factor component can be mounted on, or otherwise integrated into, the circuit board 100 and electrically connected to the conducting traces 140. When a cell with this embodiment is inserted into an energy storage system featuring an analogous circuit board, the contactors engage to provide electrical contact between the cell terminals 120, 130 and the circuit board 100. FIG. 5D depicts the male connectors 118a on the battery cell terminals 120, 130 and female sockets 118b embedded in the circuit board 100. However, it is understood that the opposite configuration is possible and is encompassed within the present disclosure.

Another alternative form is depicted in FIG. 5E, where one or more conventional or spring-loaded electrically conducting pins 122a are attached or otherwise integrated into a battery cell 110. Additionally, complementary sockets 122b or analogous electrically conductive receptacles can be embedded or otherwise integrated with a circuit board 100 such that they are in electrical contact with the traces 140 that serve as primary power conductors. An exemplary embodiment of such a modified cell and compatible board-connected componentry is shown in FIG. 5E. When a battery cell 110 with this embodiment is inserted into an energy storage system featuring an analogous circuit board 100, the pin and socket engage to provide electrical contact between the cell terminals 120, 130 and the circuit board 100. In some embodiments, the socket 122b embedded into the circuit board 100 may feature an internal form factor or mechanism which applies tension to the inserted pin 122a. FIG. 5E depicts the spring-loaded conducting pin 122a on the battery cell terminals 120, 130 and female connectors 122b attached to the circuit board 100. However, it is understood that the opposite configuration is possible and is encompassed within the present disclosure.

All of the above contacting mechanisms are particularly well-suited, but not limited, to battery cells that configure positive and negative battery terminals parallel to one another such that they can both touch or be easily extended to the plane of the circuit board. The use of direct tension connection of battery cells into a large-format energy storage system offers several advantages in terms of system performance and ease of maintenance. For instance, tension connectors can provide superior electrical contact between cells within a system. The ability to replace cells within an energy storage system without needing to sever soldered, welded, or tension connectors can also decrease the duration of system maintenance and the cost of replacement materials.

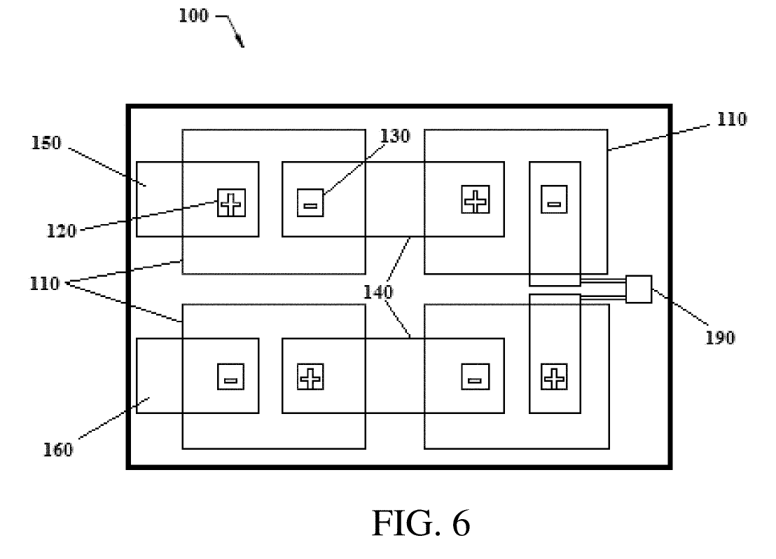

Embodiments of the described architecture may also feature additional manual or automatic mechanisms that can isolate cells or groups of cells from one another when certain conditions are satisfied. As an example, a circuit board 100 featuring series interconnections and power transfer between battery cells 110 may be fed through external circuitry that attaches to a mechanical safety lever, shield, or enclosure. If properly configured with an electrical disconnect(s) 190, the system can break the series connections between battery cells 110 upon engaging the lever, shield, or enclosure access portal. Such a disconnect mechanism 190 can serve to limit the maximum accessible voltage of a system to minimize the potential for arcing, electrocution, or other operational or safety hazards. A diagram of an exemplary configuration that electrically disconnects the second and third battery cells 110 of a four-cell series string is illustrated in FIG. 6.

Preferably, the conducting trace is as thin as possible, yet conducts as much current as possible. To reduce heat loss from resistance, the circuit trace is as wide as possible, and parallel traces are made on both sides of the board. To remove irregularities in resistance between battery cells (which can increase how soon and badly cells can become out of balance from one other), calculations can be performed to determine the width of each of the traces that needs to be between cells. Knowing the resistivity of the material of the conducting traces (for example, copper), which has units of ohms per meter, and the length of the material of the conducting traces, in units of meters, as well as the cross-sectional area of the material of the conducting traces, in units of square meters, the material resistance between cells can be balanced to make all the resistive losses exactly the same. This allows for the module series connections to be exactly the same between each battery cell with exactly the same losses between the battery cells. The circuit boards can be manufactured using standard photo plotting techniques that allow for very tight adherence to dimensions, resulting in a high repeatability of producing exactly the same amounts of conductive materials between cells. Having exactly the same amounts of conductive materials between cells provides exactly the same losses between cells.

Since resistivity is a constant and the thickness of copper (or other conductive material in the conducting traces) per side of the board is roughly constant, an equation can be generated to show that as the distance between battery cells changes (for instance, due to needed positions of the battery cells in the module), the width of the conducting traces can be adjusted to keep the resistance between cells identical. For example, the equation can be Length₁/Length₂ =Width₁/Width₂. Thus, if the distance between two battery cells is half of the distance between another two battery cells, then the width of the conducting trace between the closer-apart two battery cells should be half as wide as well in order to keep the resistance between all the battery cells exactly the same. As a result, a short circuit trace does not have to be very wide at all in order to carry a lot of current. Also, since the thickness of the conducting trace is only mils thick (which is very small in relation to the length and width of the trace), the conducting trace is essentially all of the surface area, thus allowing for maximum area for dissipating heat. Consequently, the copper foil of a conducting trace (assuming the trace is composed of copper) is able to carry much higher amounts of the current in comparison to a wire or buss bar of similar mass, or carry equal current with far less mass. Preferably, the conducting traces are provided on only the exterior surfaces of the circuit board so as to provide for maximum heat transfer to the air.

In some implementations, the energy storage system further includes one or more safety circuits that can monitor the temperature, voltage, and/or current of each battery cell, and identify faulty or abnormal battery cells. This can result in the protection of the battery cells from high temperature, overcharge, over-discharge, over-current, or the failure of any of the battery cells or modules. The safety circuits can protect battery cells from operating under abnormal conditions. The safety circuits can be configured to disconnect a battery cell from the system when the battery cell operates in any predetermined abnormal condition.

The description herein references energy storage systems featuring battery cells. However, this disclosure is not intended to be limited to systems featuring battery cells, or even to systems that are designed primarily to store electrical energy. For example, in other embodiments of this invention, the described technology may be applied to any systems that utilize capacitors, hybrid battery-capacitor cells, or other energy devices. The architecture described herein is suitable for both energy storage and energy generation applications.

The foregoing description of the embodiments has been provided for purposes of illustration and description. It is not intended to be exhaustive or to limit the invention. Individual elements or features of a particular embodiment are generally not limited to that particular embodiment but, where applicable, are interchangeable and can be used in a selected embodiment, even if not specifically shown or described. The foregoing description of the embodiments may also be varied in many ways. Such variations are not to be regarded as a departure from the invention, and all such modifications are intended to be included within the scope of the invention.

Example embodiments are provided so that this disclosure will be thorough and fully convey the scope to those who are skilled in the art. Specific details are set forth herein (such as examples of specific components, devices, and methods) to provide a thorough understanding of embodiments of this invention. It will be apparent to those skilled in the art, however, that specific details need not be employed, that the described and illustrated embodiments may be embodied in many other different forms, and that neither should be construed to limit the scope of the disclosure. In some described and illustrated embodiments, well-known processes, well-known device structures, and well-known technologies are not described in detail, but will be apparent to those skilled in the art.

The terminology used herein is for the purpose of describing the described and illustrated embodiments only and is not intended to be limiting. As used herein, the singular forms “a,” “an,” and “the” are intended to include the plural forms as well, unless the context clearly indicates otherwise. The terms “comprises,” “comprising,” “including,” and “having,” are inclusive and, therefore, specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

What is claimed is:

1. A distributed battery management system, comprising:
a plurality of battery cells including at least a first battery cell and a second battery cell, wherein each battery cell has electrical terminals comprising a negative terminal and a positive terminal;
a circuit board defining a surface and having an electrical connection to at least one of the electrical terminals; and
one or more conducting traces mounted on the surface and arranged such that:
at least one conducting trace establishes electrical contact between either (i) the negative terminal of the first battery cell and the positive terminal of the second battery cell in a series configuration, or (ii) the negative terminal of the first battery cell and the negative terminal of the second battery cell in a parallel configuration; and
at least one conducting trace is adapted to serve as a primary power conduit for one or more of the battery cells;
wherein the one or more conducting traces have an aspect ratio of at least about 1.25:1.

2. The distributed battery management system of claim 1, wherein the surface-mounted conducting traces are from about 2 mm to about 8 mm thin, and from about 1 cm to about 5 cm wide.

3. The distributed battery management system of claim 1, wherein the first battery and the second battery are thermally isolated from each other.

4. The distributed battery management system of claim 3, wherein the first battery and the second battery are spaced apart from each other so as to provide the thermal isolation between the first battery and the second battery.

5. The distributed battery management system of claim 1, further comprising a thermally insulating material between the first battery cell and the second battery cell.

6. The distributed battery management system of claim 5, wherein the thermally insulating material is selected from the group consisting of: silicon rubber, Teflon, acrylonitrile butadiene styrene, acetates, acrylics, ceramics, fiberglass laminates, thermoplastics, high impact polystyrene, polyimide, melamine, neoprene, nylon, polyethylene terephthalate, phenolics, polyolefins, polycarbonate, polysulfone, polyurethane, polyvinylchloride, polyphenylene sulfide, and combinations thereof.

7. The distributed battery management system of claim 1, wherein the electrical contact between one or more of the battery cells and the circuit board is established by means of a tension mechanism which applies mechanical pressure between a battery cell terminal and an electrical contact on the circuit board.

8. The distributed battery management system of claim 7, wherein the battery cell terminal is modified with a conductive spring, a conductive tab, a pin, or a secondary connector.

9. The distributed battery management system of claim 1, wherein the plurality of battery cells defines a first subset of battery cells, and the distributed battery management system further comprises a second subset of battery cells containing a second plurality of battery cells including at least a third battery cell and a fourth battery cell.

10. The distributed battery management system of claim 9, wherein the first battery cell is electrically adjacent to the second battery cell and the third battery cell is electrically adjacent to the fourth battery cell, and wherein the surface-mounted conducting traces are configured such that the resistance between the first battery cell terminal and the second battery cell terminal is identical to the resistance between the third battery cell terminal and the fourth battery cell terminal.

11. The distributed battery management system of claim 10, wherein the system comprises an identical amount of conductive material between the first and second battery cells as between the third and fourth battery cells.

12. The distributed battery management system of claim 1, wherein the resistance between any two battery cells in the system is identical.

13. The distributed battery management system of claim 1, wherein the surface-mounted conducting traces are configured such that the traces and/or circuit board melt or otherwise fail so as to sever an electrical connection under temperature or current levels corresponding to predetermined current and/or temperature limitations.

14. The distributed battery management system of claim 1, further comprising a balancing circuit integrated onto the circuit board.

15. The distributed battery management system of claim 1, wherein the circuit board further comprises one or more integrated circuits.

16. The distributed battery management system of claim 15, wherein the one or more integrated circuits comprises monitoring, control, or communication components or circuitry.

17. The distributed battery management system of claim 1, wherein the system balances at a power rating of from about 2 watts per battery cell to about 30 watts per battery cell.

18. The distributed battery management system of claim 1, wherein series interconnections and/or power transfer between the battery cells are fed through external circuitry attached to a mechanical safety lever, shield, or enclosure.

19. The distributed battery management system of claim 18, further comprising an electrical disconnect configured to break the series connections upon engagement of the safety lever, shield, or enclosure.

20. An energy generation or storage system featuring a distributed energy management system comprising:
a circuit board in electrical communication with subsets of a plurality of energy generation components or energy storage components, wherein the size of each subset ranges from a single energy generation component or energy storage component to all energy generation components or energy storage components within the system, each energy generation component or energy storage component having electrical terminals comprising a negative terminal and a positive terminal; and
one or more surface-mounted conducting traces arranged such that:
at least one surface-mounted conducting trace establishes electrical contact between either: (i) the negative terminal of one energy generation component or energy storage component and the positive terminal of an adjacent energy generation component or energy storage component in a series configuration; or (ii) two or more negative terminals and/or two or more positive terminals of adjacent energy generation components or energy storage components in a parallel electrical configuration; and
at least one surface-mounted conducting trace serves as a primary power conduit for one or more of the electrically contacted energy generation components or energy storage components.

21. The energy generation or storage system featuring a distributed energy management system of claim 20, wherein the electrical communication is established by a tension mechanism which applies mechanical pressure between a modified or unmodified energy generation component or energy storage component terminal and an electrical contact on the circuit board.

22. The energy generation or storage system featuring a distributed energy management system of claim 20, wherein the surface-mounted conducting traces are configured such that the resistance between one energy generation component or energy storage component terminal and the terminal of an electrically adjacent energy generation component or energy storage component is identical to the resistance between another energy generation component or energy storage component terminal and a respective electrically adjacent energy generation component or energy storage component terminal within the battery system.

23. The energy generation or storage system featuring a distributed energy management system of claim 20, wherein the surface-mounted conducting traces are configured such that the conducting trace and/or the circuit board melts or otherwise fails so as to sever the corresponding electrical connection under temperature or current levels corresponding to predetermined current and/or temperature limitations.

24. The energy generation or storage system featuring a distributed energy management system of claim 20, further comprising a balancing circuit integrated onto the circuit board.

25. The energy generation or storage system featuring a distributed energy management system of claim 20, wherein the circuit board further comprises one or more integrated circuits.

26. The energy generation or storage system featuring a distributed energy management system of claim 25, wherein the one or more integrated circuits comprises monitoring, controls, or communication components or circuitry.

27. The energy generation or storage system featuring a distributed energy management system of claim 20, wherein the energy generation components or energy storage components comprise fuel cells, capacitors, hybrid battery-capacitors, or a combination thereof.

28. A method of isolating a fault in a battery storage system, the method comprising:
providing a battery storage system comprising circuit boards having surface-mounted conducting traces, wherein the conducting traces electrically connect the circuit boards to a plurality of battery cells; and
tuning the dimensions of the conducting traces so as to cause the conducting traces to melt at a predetermined current and/or temperature level and thereby isolate a fault in the battery storage system.
